(19) United States
(12) Patent Application Publication
(10) Pub. No.: US 2008/0220548 A1
(43) Pub. Date: Sep. 11, 2008

(54) MULTI-CHIP SURFACE MOUNTED LED STRUCTURE AND A METHOD FOR MANUFACTURING THE SAME

(76) Inventors: Tsung-Wen CHAN, Taipei City (TW); Chin-Hsiang Ku, Taipei City (TW)

Correspondence Address: SINORICA, LLC, 528 FALLSGROVE DRIVE, ROCKVILLE, MD, 20850, US

(21) Appl. No.: 11/683,624

(22) Filed: Mar. 8, 2007

(51) Int. Cl. H01L 33/00

(52) U.S. Cl. 438/26; 257/E33.057

(57) ABSTRACT

A multi-chip surface mounted LED structure and a method for manufacturing the same, said LED structure comprises a plurality of equivalent lighting units, each lighting unit comprises an LED chip, a heat sink structure, two opposing electrodes, said plurality of equivalent lighting units are mutually connected by a supporting structure; said method comprises the steps of firstly cutting a metal material belt to form a basic shape and using plastic injection molding to form said supporting structure, and then using chip bonding and wire bonding to connect said two opposing electrodes, and connecting adjacent lighting units in series/parallel, and finally cutting off a spare region of said metal material belt and packaging sad LED structure to form said multi-chip surface mounted LED structure; furthermore, a plurality of multi-chip surface mounted LED structures can be mutually connected in series/parallel by directly cutting said metal material belt to form a connection area thereon to enable conductivity between adjacent multi-chip surface mounted LED structures.

### BACKGROUND OF THE INVENTION

1. Field of the Invention

The present invention relates to a multi-chip surface mounted LED structure and a method for manufacturing the same, and more particularly, to an LED manufacturing technique which can provide a heat sink structure to surface mounted LEDs to reduce energy loss and to simplify manufacturing and also contributes to environmental conservation.

2. Description of the Prior Art

Among all kinds of optoelectronics components, LED (Light Emitting Diode) have the advantages of small form factor, long lifetime, fast response, energy saving, shock proof, low cost and volume production capability, therefore LED has long been used in a wide range of application and has the greatest market value among various optoelectronics components.

LED is a lighting component built by semiconductor process and has two electrode terminals. The basic operation of LED is that, when applying voltage between two electrodes, a small current would be generated to trigger the combination of electrons and holes inside the LED, the energy released from electrons/holes combination is radiated in the form of light. Also, different from general light bulbs, LED is a cold lighting source, which provides advantages such as low energy consumption, long lifetime, zero warm-up time, and fast response time. Furthermore, LED has small form factor, and it is shock proof and suitable for volume production and for building small or array type components. Therefore, LEDs have been widely adopted in indicators and display devices used in information, communication and consumer electronics. LED chips are packaged based on different requirements of end products into different kinds of LEDs, which include LEDs of lamp type, cluster type, digit display type, dot matrix type and surface mounted (SMD) type, wherein SMD type provides smaller footprint than other type, therefore it is used in backlight module and keypad of cellular phone with high market demands.

The above-mentioned LED does not have heat dissipation problem since it generates less heat than a general light bulb. However, the emerging high-brightness LED products would generate considerably more heat than the above-mentioned LED, let alone LED array. Therefore, in modern design of LED, heat sink structure has become a necessity in the manufacturing process.

The FIG. 4 of U.S. Pat. No. 7,138,660 disclosed a traditional SMD type LED having its LED chip disposed on the anode and then routing it wires from the LED chip to the anode and the cathode. The packaged SMD type LED doesn't need additional optical components or reflector to keep the light path parallel to respective circuit board. This SMD type LED uses metal disposed on the anode to dissipate heat to the outside.

However, the above mentioned LED structure or other types of LED products often encounter the following heat dissipation problems, which need to be dealt with:

1. The heat dissipating mechanism used in traditional LED can not efficiently handle all the generated heat, which cause the brightness to degrade when LED's temperature goes up, furthermore, when the temperature passes beyond 85° C., the degradation will worsen.

2. The phosphor used in LED packaging tends to absorb moisture if its temperature goes too high, and then the moisture would darken the phosphor to reduce the lighting efficiency and the capability of LED.

3. Traditional LED design uses copper foil on PCB to dissipate heat; however, due to low heat dissipating efficiency of the two electrodes, it is not a viable solution to dissipate all the heat generated by LED.

4. Traditional LED design uses soldering to connect multiple LED chips in series/parallel, it is likely that a lot of solder points could be used, therefore, this design doesn't conform to the Restriction of the use of certain hazardous substance in EEE (ROHS) regulation set by the EU. The objective of ROHS is to limit the use of hazardous material used in electrical/electronics devices to protect human health and the environment as well.

In view of the above-described deficiencies of traditional LED products and the method for manufacturing the same, after years of constant effort in research and practical applications, the inventor of this invention has consequently developed and proposed an enhanced structure for SMD type LED and also its manufacturing method in the present invention to provide both a simple design and low energy consumption design.

### SUMMARY OF THE INVENTION

It is an objective of the present invention to provide a multi-chip surface mounted LED structure and a method for manufacturing the same. The present invention uses an added heat sink structure to fully dissipate heat generated by LEDs and to effectively extend product lifetime and lighting efficiency without adding too much cost.

It is another objective of the present invention to provide a multi-chip surface mounted LED structure and a method for manufacturing the same, wherein its heat sink structure is able to combine with the heat dissipating mechanism on the PCB to more efficiently dissipate heat generated by LEDs.

It is still another objective of the present invention to provide a multi-chip surface mounted LED structure and a method for manufacturing the same, since no soldering process is used in connecting LED chips in series/parallel, the present invention conforms to EU's RoHs regulation.

It is still another objective of the present invention to provide a multi-chip surface mounted LED structure and a method for manufacturing the same. The present invention can integrate single point lighting sources into a whole lighting plane by connecting LED chips in series/parallel. Therefore it can be used in wider range of applications.

The multi-chip surface mounted LED structure comprises a plurality of equivalent lighting units, each lighting unit comprises an LED chip and its heat sink structure in contact, two opposing electrodes are disposed besides the LED chip, while two conducting wires are distributed around the LED chip and extend from the LED chip to the two opposing electrodes; the heat sink structure and the two opposing electrodes are formed on the same metal material belt; two adjacent light units are connected in series/parallel by the conducting wire or metal material belt, a support structure is fixed to the plurality of lighting units to hold the respective heat sink structure and the two opposing electrodes in position.

Therefore, the method for manufacturing a multi-chip surface mounted LED structure starts by firstly cutting off a spare region other than those which form a heat sink structure and two opposing electrodes on a metal material belt to form a basic shape for the heat sink structure and the two opposing electrodes on the metal material belt; using plastic mold injection to form a support structure on the metal material belt for the support structure to fix a plurality of heat sink structures and two opposing electrodes in a unit area; and then implementing wire bonding and chip bonding on the metal material belt having basic shape and connecting a plurality of LED chips inside the multi-chip surface mounted LED in series/parallel; and finally cutting off crop areas such as the connection regions between the heat sink structure and relative electrodes of different LED chips, and packaging the multi-chip surface mounted LED structure and cutting off the multi-chip surface mounted LED structure from the metal material belt.

Besides, more than one set of multi-chip surface mounted LED structures are connected in series/parallel by forming a connection area on the same metal material belt, wherein the connection area conducts the two adjacent multi-chip surface mounted LED structures to provide versatile product selections.

### BRIEF DESCRIPTION OF THE DRAWINGS

The drawings disclose an illustrative embodiment of the present invention which serves to exemplify the various advantages and objects hereof, and are as follows:

FIG. 1 illustrates a flow chart of the method for manufacturing a multi-chip surface mounted LED structure disclosed in the present invention;

FIG. 2 illustrates the structure by cutting off a spare metal material belt region in the first step;

FIG. 3 illustrates the placement of support structure in the second step;

FIG. 4 illustrates the wire bonding and chip bonding structures in the third step;

FIG. 5 illustrates the cut metal material belt structure after the fourth step;

FIG. 6 illustrates the packaged LED structure in the fifth step;

FIG. 7 illustrates a flow chart of the method for manufacturing a multi-chip surface mounted LED structure in another embodiment disclosed in the present invention;

FIG. 8 illustrates the cut metal material belt structure after the fourth step in another embodiment disclosed in the present invention;

FIG. 9 illustrates the packaged LED structure in the fifth step in another embodiment disclosed in the present invention;

FIG. 10 illustrates the real circuit view of another embodiment disclosed in the present invention; and

FIG. 11 illustrates an equivalent circuit of another embodiment disclosed in the present invention.

[Reference Numeral]

| F10 | Step 1 | F11 | Step 2 |
|---|---|---|---|
| F12 | Step 3 | F13, F15 | Step 4 |
| F14, F16 | Step 5 | 10 | multi-chip surface mounted |
| | | | LED structure |
| 100 | lighting unit | 1 | LED chip |
| 2 | heat sink structure | 31, 32 | electrode |
| 41, 42, 43 | conducting wire | 5 | support structure |
| 6 | metal material belt | 61 | spare region |
| 62 | crop area | 63 | cutting line |
| 64 | connection area | | |

F10: cutting off a spare region other than those which form the heat sink structure and the two electrodes on the metal material belt;

F11: using plastic mold injection to form the support structure 5;

F12: implementing wire bonding and chip bonding on the metal material belt having basic shape, and connecting the relative electrodes on two adjacent lighting units 100 in parallel;

F13: cutting off crop area to let the heat sink structure and the electrodes of each lighting unit to form an independent body;

F14: packaging the multi-chip surface mounted LED structure and cutting off a the multi-chip surface mounted LED structure from the metal material belt;

F15: cut off crop area between the heat sink structure and the electrodes, yet two adjacent multi-chip surface mounted LED structures are connected in series via a connection area;

F16: packaging the LED structure to form the packaged multi-chip surface mounted LED structure, wherein two adjacent multi-chip surface mounted LED structure are connected in series;

### DETAILED DESCRIPTION OF THE PREFERRED EMBODIMENT

The present invention will now be described by preferred embodiment along with accompanying drawings for better understanding of the structure, feature and performance of the LED structure disclosed in the present invention.

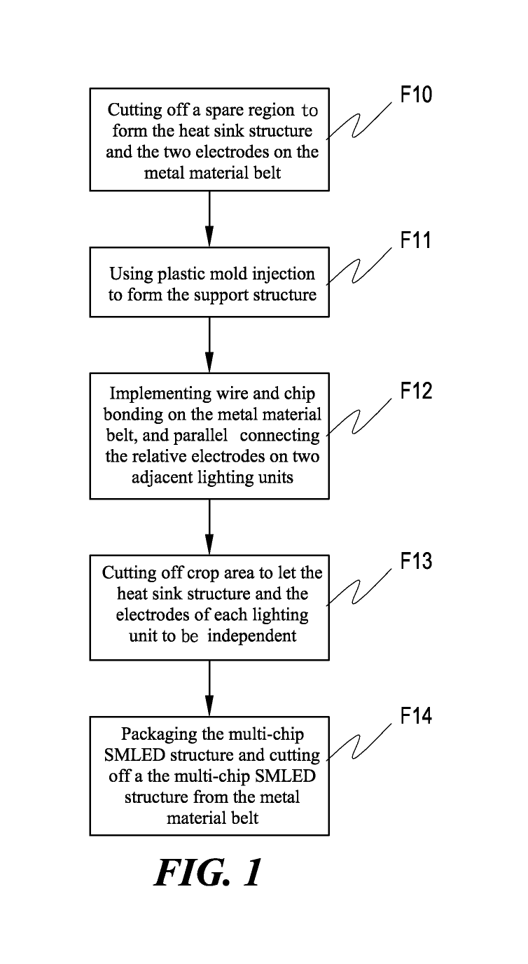

Please refer to FIG. 1 to 6 for the method for manufacturing a multi-chip surface mounted LED structure 10; the multi-chip surface mounted LED structure 10 comprises more than one lighting units 100, while in this embodiment the number of lighting units is 3; each lighting unit 100 comprises an LED chip 1, the LED chip 1 is disposed on the heat sink structure 2, while two electrodes 31,32 are disposed besides the heat sink structure 2, two conducting wires 41, 42 extend from the LED chip 1 to two electrode 31, 32, and the heat sink structure 2 and two electrode 31, 32 are formed on the same metal material belt 6; between adjacent lighting units, the relative electrodes 31 are connected in parallel by a conducting wire 43, the electrode 32 on each lighting unit extends to the metal material belt 6 to connect in parallel; a support structure 5 is disposed between the heat sink structure 2 and the electrode 31, 32 of the multi-chip surface mounted LED structure 10 for fixing the heat sink structure 2 and the electrode 31, 32, and then the multi-chip surface mounted LED structure 10 is packaged using traditional LED packaging method to form the packaged multi-chip surface mounted LED structure 10.

Subsequently, in practical use, the multi-chip surface mounted LED structure 10 is connected via two electrodes 31, 32 to a PCB using surfaced mounted (SMD) method, then it is electrically conducted to let the LED chip 1 start to emit light, the heat generated by the LED chip 1 would be dissipated via the heat sink structure 2 to other places, if necessary, it is viable to combine the heat sink structure 2 with the heat dissipating mechanism on the PCB to dissipate the heat out of the PCB; since the heat sink structure 2 doesn't have any contact with any electrode, it would remain neutral electrically and would not interfere the operation of other circuitry.

Moreover, the heat sink structure 2 can be bent into various shapes in order to cooperate with other heat dissipating device or to change the space arrangement to provide the best dissipating efficiency; or the heat sink structure 2 has adjustable area to achieve the best heat dissipating effect.

The method for manufacturing the multi-chip surface mounted LED structure 10 comprises the following steps:

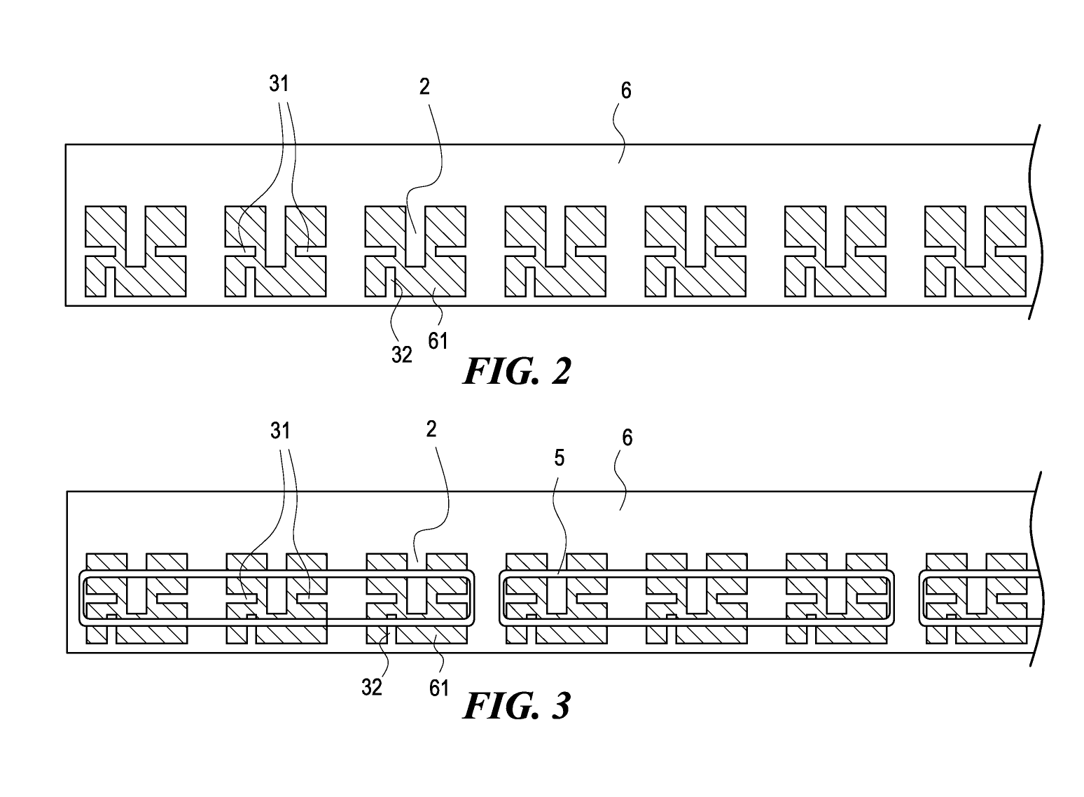

Step 1 (F10): as shown in FIG. 2, firstly using a knife mold to cut off a spare region 61 other than those which form the heat sink structure 2 and the two electrode 31, 32 on the metal material belt to form a basic shape for the heat sink structure 2 and the two electrodes 31, 32 on the metal material belt 6;

Step 2 (F11): as shown in FIG. 3, using plastic mold injection to form the support structure 5 in the range of the multi-chip surface mounted LED structure 10 for the support structure 5 to fix a plurality of heat sink structures 2 and electrodes 31, 32;

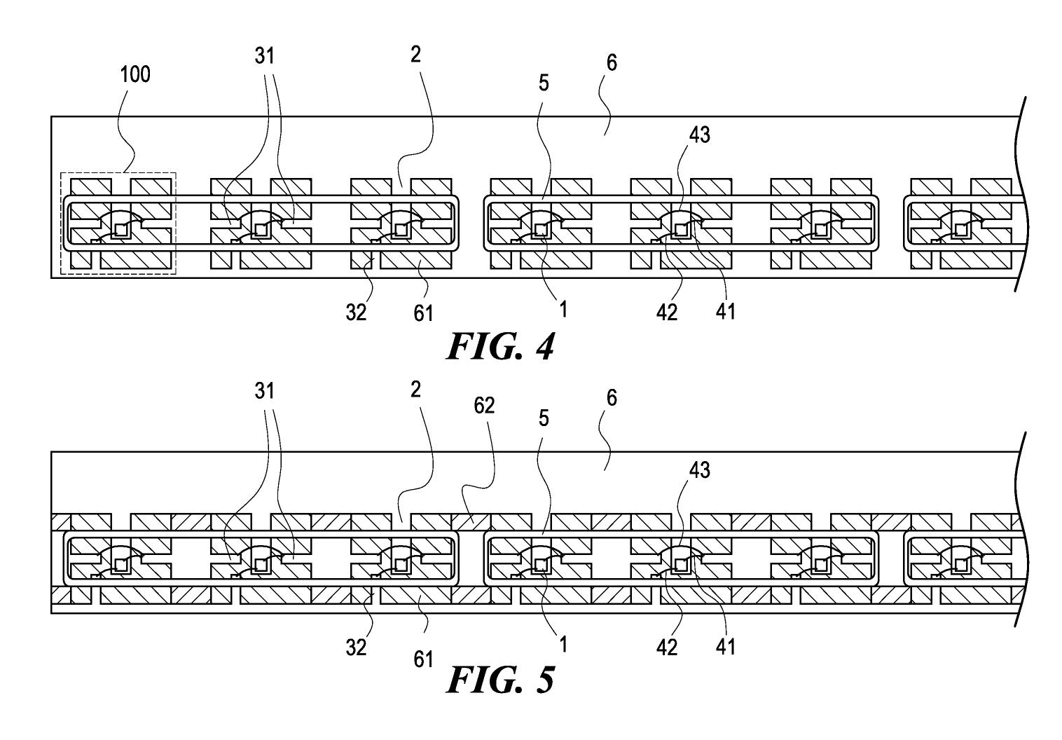

Step 3 (F12): as shown in FIG. 4, implementing wire bonding and chip bonding on the metal material belt 6 having basic shape, and placing the LED chip 1 on the heat sink structure 2, and then extending two conducting wires 41, 42 from the LED chip 1 to two electrodes 31, 32 respectively, and connecting the relative electrodes 31 on two adjacent lighting units 100 in parallel by a conducting wire 43;

Step 4 (F13): as shown in FIG. 5, using another knife mold to cut off connection area such as the crop area 62 between the heat sink structure 2 and the electrodes 31, 32 to let the heat sink structure 2 and the electrodes 31, 32 of each lighting unit 100 to form an independent body, yet to be fixed in position by the design of the support structure 5;

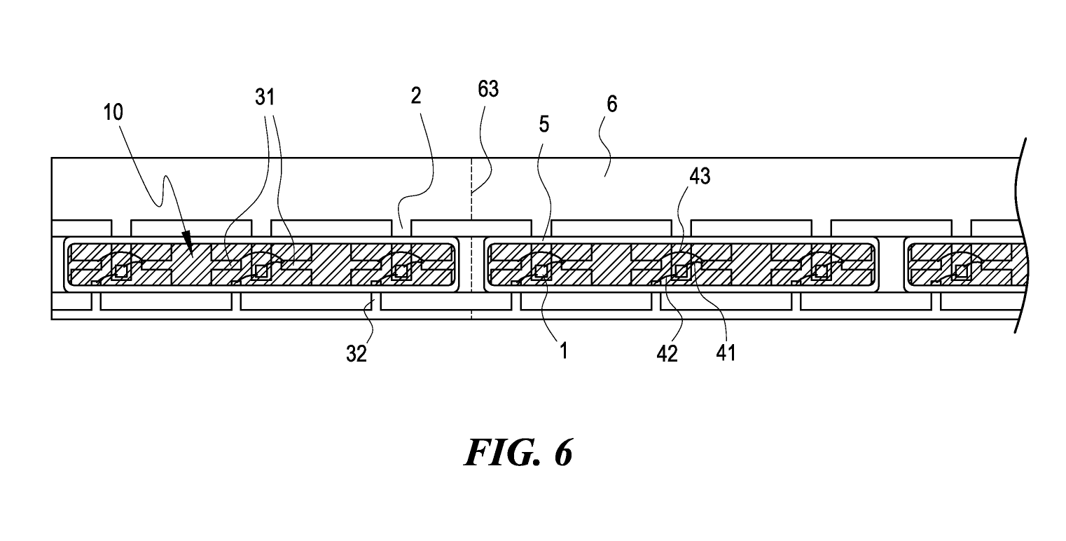

Step 5 (F14): as shown in FIG. 6, packaging the multi-chip surface mounted LED structure 10 and cutting off a desired size of the multi-chip surface mounted LED structure 10 along a cutting line 63 from the metal material belt 6, therefore the present invention is completed.

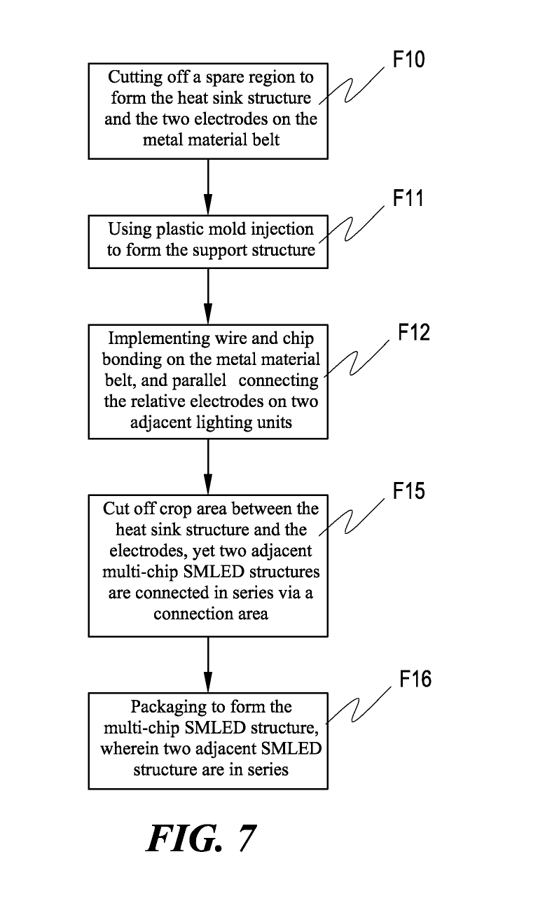

Please refer to FIG. 7 to 11 for another embodiment of the structure and method for manufacturing a multi-chip surface mounted LED structure 10; this embodiment further generate an LED structure having series/parallel connection, in which Step 1 to Step 3 are the same as the previous embodiment, and the following steps are described below:

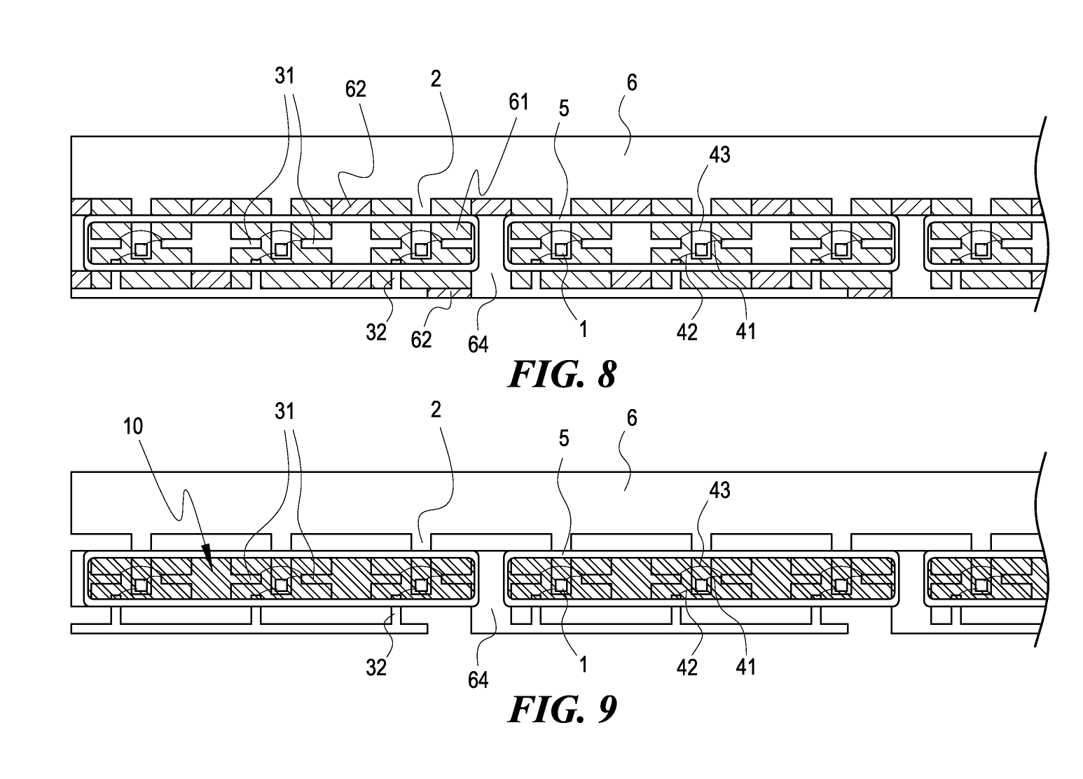

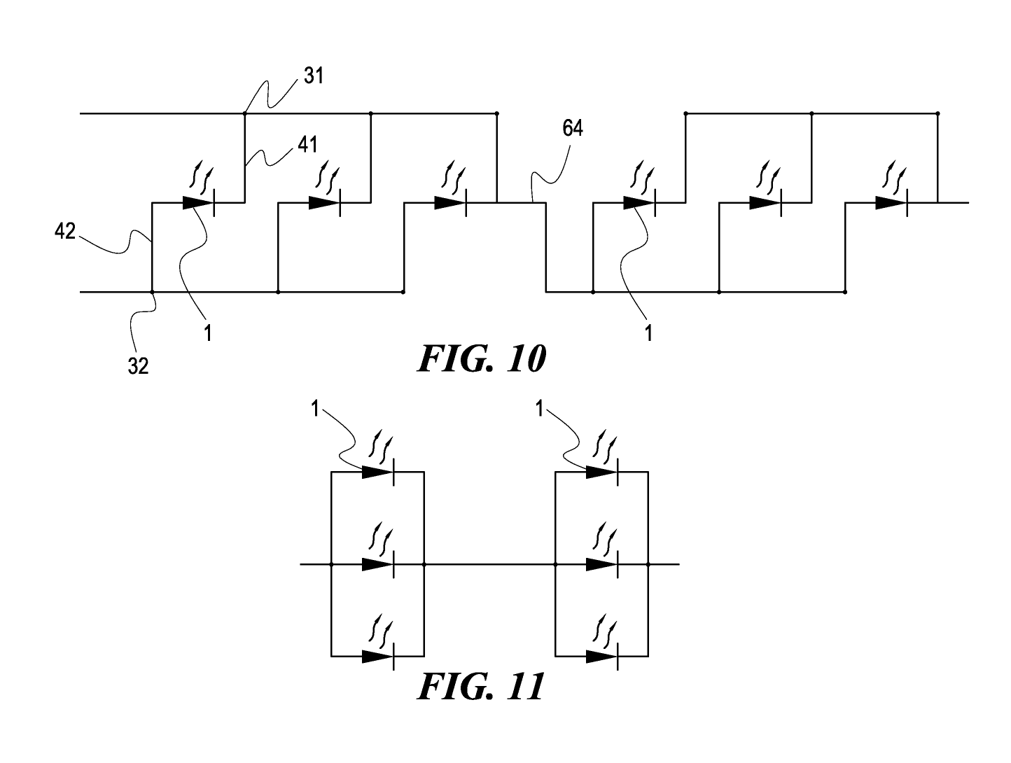

Step 4 (F15): as shown in FIG. 8, using another knife mold to cut off connection area such as the crop area 62 between the heat sink structure 2 and the electrodes 31, 32, yet two adjacent multi-chip surface mounted LED structures 10 are connected via a connection area 64 left on the metal material belt 6, wherein the electrode 31 and 32 of the lighting unit 100 form the series/parallel connection as shown in FIG. 10 and FIG. 11, and the heat sink structure 2 and the electrodes 31, 32 of each lighting unit 100 are fixed in position by the design of the support structure 5;

Step 5 (F16): as shown in FIG. 9, packaging the LED structure to form the packaged multi-chip surface mounted LED structure 10, wherein each multi-chip surface mounted LED structure 10 has a plurality of lighting units connected in parallel, while two adjacent multi-chip surface mounted LED structure 10 are connected in series.

Therefore, the present invention eliminates the need for soldering in connecting multiple LED chips in series/parallel to meet the requirement of environmental conservation and to greatly improve the production efficiency.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A method for manufacturing a multi-chip surface mounted LED structure, comprising the following steps:
Step 1: using a knife mold to cut off a spare region other than those which form a heat sink structure and two opposing electrodes on a metal material belt to form a basic shape for said heat sink structure and said two opposing electrodes on said metal material belt;
Step 2: disposing a support structure on said metal material belt for said support structure to fix a plurality of heat sink structures and two opposing electrodes;
Step 3: implementing wire bonding and chip bonding on said metal material belt having said basic shape, and connecting a plurality of LED chips inside said multi-chip surface mounted LED in series/parallel;
Step 4: cutting off connection regions between said heat sink structure and relative electrodes of different LED chips, yet said multi-chip surface mounted LED structure being fixed in position by said support structure; and
Step 5: packaging said multi-chip surface mounted LED structure and cutting off said multi-chip surface mounted LED structure from said metal material belt.

2. The method of claim 1, wherein said support structure is disposed by mold injection.

3. The method of claim 1, wherein said plurality of LED chips are connected in series/parallel by cutting said metal material belt to take shapes.

4. The method of claim 1, wherein said plurality of LED chips are connected in series/parallel through conducting wires to take shapes.

5. A method for manufacturing a multi-chip surface mounted LED structure, comprising the following steps:
Step 1: using a knife mold to cut off a spare region other than those which form a heat sink structure and two opposing electrodes on a metal material belt to form a basic shape for said heat sink structure and said two opposing electrodes on said metal material belt;
Step 2: disposing a support structure on said metal material belt for said support structure to fix a plurality of heat sink structures and relative two opposing electrodes;
Step 3: implementing wire bonding and chip bonding on said metal material belt having basic shape, and connecting a plurality of LED chips inside said multi-chip surface mounted LED in series/parallel;
Step 4: cutting off connection regions between said heat sink structure and relative electrodes of different LED chips, yet two adjacent multi-chip surface mounted LED structures are connected via a connection area left on said metal material belt and are fixed in position by said support structure; and
Step 5: packaging said multi-chip surface mounted LED structure and cutting off said multi-chip surface mounted LED structure from said metal material belt.

6. The method of claim 5, wherein said support structure is disposed by mold injection.

7. The method of claim 5, wherein said plurality of LED chips are connected in series/parallel by cutting said metal material belt to take shapes.

8. The method of claim 5, wherein said plurality of LED chips are connected in series/parallel through conducting wires to take shapes.

9. A multi-chip surface mounted LED structure, comprises:
a plurality of equivalent lighting units, lighting units are mutually connected in series/parallel, each lighting unit comprises an LED chip, a heat sink structure, two opposing electrodes, said LED chip is fixed on said heat sink structure and acts as an light source, two conducting wires are distributed around said LED chip and extend from said LED chip to said two opposing electrodes; and
a support structure, said support structure is fixed to said plurality of lighting units to hold said heat sink structure and said two opposing electrodes in position.

10. The multi-chip surface mounted LED structure of claim 9, wherein said heat sink structure can combine other heat dissipating device to provide more efficient heat dissipating effect.

11. The multi-chip surface mounted LED structure of claim 9, wherein said heat sink structure can be bent into various shapes to achieve the most heat dissipating effect.

12. The multi-chip surface mounted LED structure of claim 9, wherein said heat sink structure has adjustable area to achieve the most heat dissipating effect.

13. The multi-chip surface mounted LED structure of claim 9, wherein said heat sink structure and said two opposing electrodes are formed on said metal material belt at the same time.

14. The multi-chip surface mounted LED structure of claim 9, wherein more than one set of multi-chip surface mounted LED structures are disposed with a connection area between them, said connection area is connected in series/parallel.

15. The multi-chip surface mounted LED structure of claim 14, wherein said connection area, said heat sink structure and said two opposing electrodes are formed on said metal material belt at the same time.
